(19) United States
(12) Patent Application Publication
(10) Pub. No.: US 2015/0273798 A1
(43) Pub. Date: Oct. 1, 2015

(54) ELASTIC COMPONENT SUBSTRATE AND PREPARATION METHOD THEREOF

(71) Applicant: UBRIT CO., LTD., New Taipei City (TW)

(72) Inventor: Szu-Wei SUN, Taoyuan County (TW)

(21) Appl. No.: 14/516,576

(22) Filed: Oct. 16, 2014

(30) Foreign Application Priority Data
Mar. 27, 2014 (TW) 103111537
Aug. 6, 2014 (TW) 103126929

(51) Int. Cl. B32B 7/12; B32B 37/18; B32B 27/08; H05K 3/00; B32B 27/36; B32B 27/28; B32B 37/12; B32B 38/00

(52) U.S. Cl. CPC B32B 7/12; B32B 37/1284; B32B 37/182; B32B 38/0008; H05K 3/0064; B32B 27/365; B32B 27/36; B32B 27/283; B32B 27/08; B32B 2457/08; B32B 2250/03

(57) ABSTRACT

A method of manufacturing an elastic component substrate includes following steps. An elastic component is provided, and a heat process is applied to the elastic component. A light-curing adhesive glue layer is smeared on a bottom of the elastic component, which a Shore A hardness value of the light-curing adhesive glue layer is lower than 90, and the elastic component is disposed on a surface of a substrate. The light-curing adhesive glue layer is cured by irradiating light on the light-curing adhesive glue layer, and the elastic component is adhered on the surface of the substrate by the light-curing adhesive glue layer.

### RELATED APPLICATIONS

This application claims priority to Taiwan Application Serial Number 103111537, filed on Mar. 27, 2014 and Taiwan application serial no. 103126929, filed on Aug. 6, 2014, which are herein incorporated by reference.

### BACKGROUND

1. Field of Invention

The present disclosure relates to an elastic component substrate and a preparation method thereof.

2. Description of Related Art

A keyboard is an equipment to operate a machine or a device by arranging through a system, and the main function of the keyboard is data input. It is generally used in various electronic devices, such as home computers, laptops, personal mobile devices, or other similar electronic devices. Comparing with a traditional mechanical keyboard, a membrane keyboard generates much lower voices when pressing buttons on the keyboard. Besides, there is no mechanical wear on the membrane keyboard, and cost required to produce the membrane keyboard is much lower. Therefore, the membrane keyboard has been widely used for the public.

Generally, a process of manufacturing keyboard buttons begins with smearing adhesive glue on a bottom of an elastic component, and then the elastic component is disposes on a substrate with a printed circuit thereon. After smearing the adhesive glue, the elastic component and the substrate are baked at high temperature to cure the adhesive glue. The elastic component could be adhered on the substrate by the cured adhesive glue, and the adaptation between the elastic component and the substrate is enhanced. But the plastic substrate will become deforming or bending when baking at high temperature, and thus affects size accuracy of the elastic component substrate seriously.

### SUMMARY

The invention provides a manufacturing method to adhere an elastic component on a substrate. The process improves the general process of manufacturing the elastic component substrate, and thus effectively reduces the situation of the substrate becomes bending or deformation. Also, time of curing the elastic component on a substrate could be reduced.

An aspect of the invention is to provide a method of manufacturing an elastic component substrate. An elastic component is provided, and a heat process is applied to the elastic component. A light-curing adhesive glue layer is smeared on a bottom of the elastic component, which a Shore A hardness value of the light-curing adhesive glue layer is lower than 90, and the elastic component is disposed on a surface of a substrate. The light-curing adhesive glue layer is cured by irradiating light on the light-curing adhesive glue layer, and the elastic component is adhered on the surface of the substrate by the light-curing adhesive glue layer.

In one or more embodiments, the elastic component is formed of silicone.

In one or more embodiments, the heat process is processed by a flame treatment machine.

In one or more embodiments, the substrate is a polymer membrane.

In one or more embodiments, the polymer membrane is formed of poly(ethylene terephthalate) or polycarbonate.

In one or more embodiments, the substrate is a blank substrate or a substrate including a printed circuit.

In one or more embodiments, the light is ultraviolet light.

An aspect of the invention is to provide an elastic component substrate. The elastic component substrate includes a substrate, a light-curing adhesive glue layer and an elastic component. A Shore A hardness value of the light-curing adhesive glue layer is lower than 90. A bottom of the elastic component is adhered on a surface of the substrate by the light-curing adhesive glue layer, which the bottom of the elastic component includes a bottom adhesive layer filled with light-curing adhesive glue. The bottom adhesive layer is in contact with the light-curing adhesive glue layer.

In one or more embodiments, the substrate is a polymer membrane.

In one or more embodiments, the polymer membrane is formed of poly(ethylene terephthalate) or polycarbonate.

In one or more embodiments, the substrate is a blank substrate or a substrate including a printed circuit.

In one or more embodiments, the elastic component is formed of silicone.

In one or more embodiments, the bottom of the elastic component also includes an internal region, which the bottom adhesive layer is between the internal region and the light-curing adhesive glue layer.

In one or more embodiments, the light-curing adhesive glue layer is an ultraviolet light-curing adhesive glue layer.

It is to be understood that both the foregoing general description and the following detailed description are by examples, and are intended to provide further explanation of the invention as claimed.

### BRIEF DESCRIPTION OF THE DRAWINGS

The invention could be more fully understood by reading the following detailed description of the embodiment, with reference made to the accompanying drawings as follows:

FIG. 1 is an exploded view of an elastic component substrate, in accordance with some embodiments.

FIG. 2 is a cross-sectional view of the elastic component substrate, in accordance with some embodiments.

FIG. 3 is an enlarged view of a contact area between the elastic component and the substrate, in accordance with some embodiments.

FIG. 4 is a diagrammatic view of a method of manufacturing an elastic component substrate, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Reference will now be made in detail to the present embodiments of the invention, examples of which are illustrated in the accompanying drawings. Wherever possible, the same reference numbers are used in the drawings and the description to refer to the same or like portions.

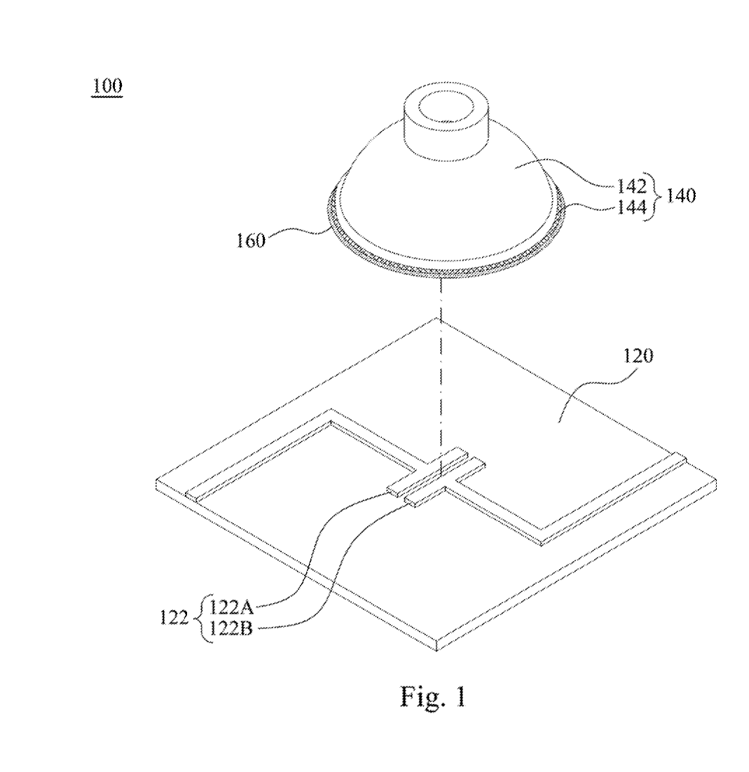

Please referring to FIG. 1, FIG. 1 is an exploded view of an elastic component substrate in accordance with various embodiments. As shown in FIG. 1, an elastic component substrate 100 includes a substrate 120, an elastic component 140 and a light-curing adhesive glue layer 160. More specifically, the elastic component substrate 100 includes the substrate 120, and a printed circuit 122 is on a surface of the substrate 120. The printed circuit includes a first conductive portion 122A and a second conductive portion 122b. Since the first conductive portion 122A and the second conductive portion 122b are separated and electrically isolated, the printed circuit 122 is off. In embodiments, the substrate 120 is a polymer membrane. In some embodiments, the polymer membrane is formed of poly ethylene terephthalate) or polycarbonate.

Continuing in FIG. 1, the light-curing adhesive glue layer 160 is on a bottom of the elastic component 140, and a Shore A hardness value of the light-curing adhesive glue layer 160 is lower than 90. Because the hardness of the light-curing adhesive glue layer 160 is much softer than the traditional light-curing adhesive glue, the light-curing adhesive glue layer 160 reduces strains and stresses when curing the elastic component 140 on the substrate 120. After curing, the elastic component 140 is conformed to specification, and the stability of the elastic component substrate 100 is enhanced significantly. The elastic component 140 is adhered on the surface of the substrate 120 by the light-curing adhesive glue layer 160, which the elastic component 140 is disposed above the first conductive portion 122A and the second conductive portion 122b. Besides, the elastic component 140 includes an internal region 142 and a bottom adhesive layer 144. The bottom adhesive layer 144 is between the internal region 142 and the light-curing adhesive glue layer 160, which the bottom adhesive layer 144 is filled with light-curing adhesive glue. In embodiments, the elastic component 140 is formed of silicone. In various embodiments, the substrate 120 is a blank substrate without the printed circuit 122 thereon.

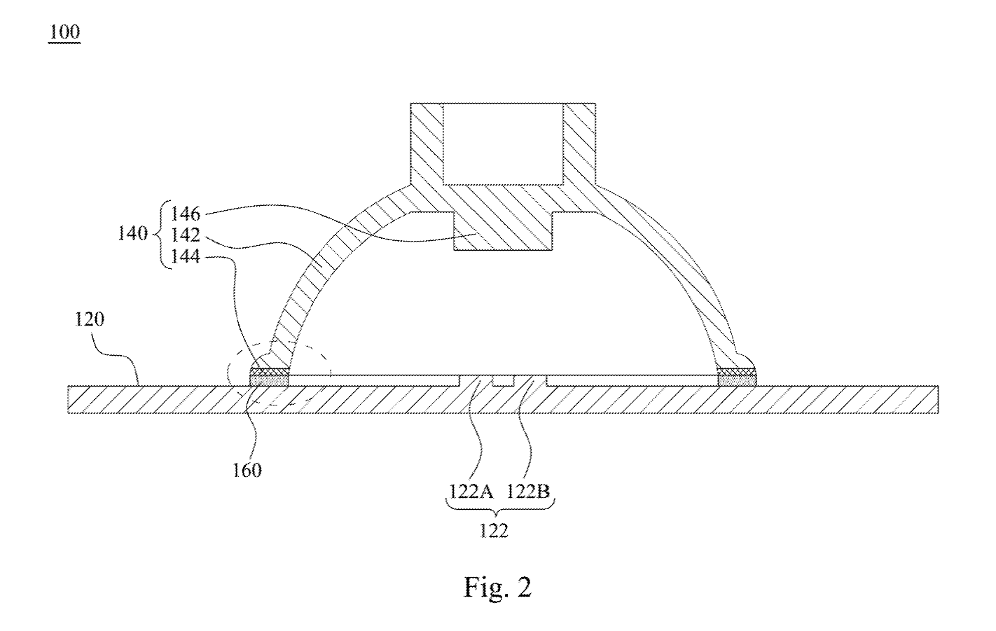

Referring to FIG. 2, and referring to FIG. 1 at the same time to further clarify the present disclosure. FIG. 2 is a cross-sectional view of the elastic component substrate 100 in FIG. 1. As shown in FIG. 2, the elastic component 140 is adhered on the substrate 120 by the light-curing adhesive glue layer 160 on the bottom of the elastic component 140, and the elastic component 140 is above the first conductive portion 122A and the second conductive portion 122b. The elastic component 140 also includes a contact portion 146 made of conductive material. The elastic component 140 is deformed when being pressed by an external force, and the contact portion 146 will contact the first conductive portion 122A and the second conductive portion 122b. Since the first conductive portion 122A and the second conductive portion 122b are electrically connected, the printed circuit 122 is on. More specifically, when the elastic component 140 responses to the external force and being pressed vertically, the contact portion 146 moves downward at the same time. The contact portion 146 makes the first conductive portion 122A electrically connect to the second conductive portion 122b, and a closed loop of the printed circuit 122 is formed. After the external force disappears, the elastic component 140 is recovered to its original shape. Therefore, there is no contact between the contact portion 146, the first conductive portion 122A and the second conductive portion 122B, the printed circuit 122 is disconnected.

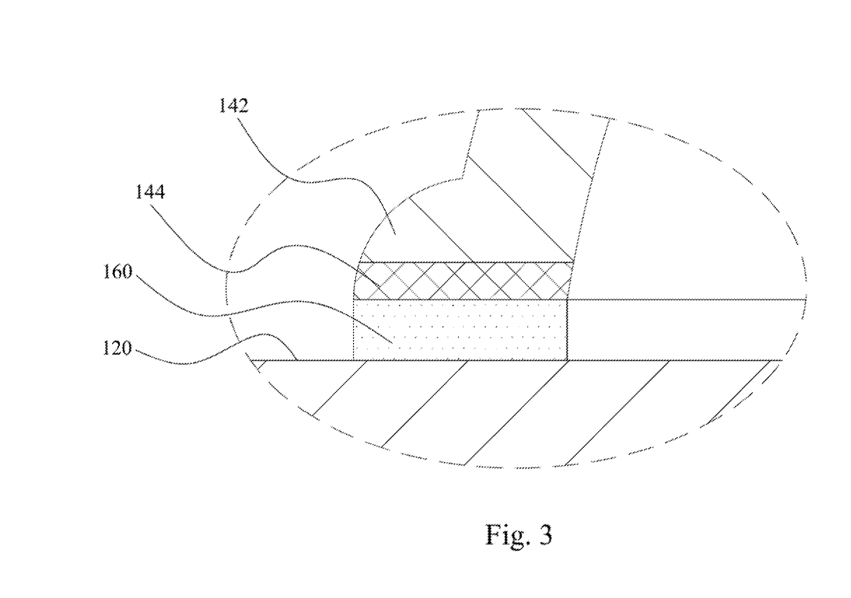

Please referring to FIG. 3, FIG. 3 is an enlarged view of a contact area between the elastic component 140 and the substrate 120. As shown in FIG. 3 the elastic component 140 is adhered on the surface of the substrate 120 by the light-curing adhesive glue layer 160, which is on the bottom of the elastic component 140. Because the bottom adhesive layer 144 of the elastic component 140 is in contact with the light-curing adhesive glue layer 160, some light-curing adhesive glue will flow into and fill the bottom adhesive layer 144. On the other hand, the internal region 142 of the elastic component 140 is not filled with the light-curing adhesive glue.

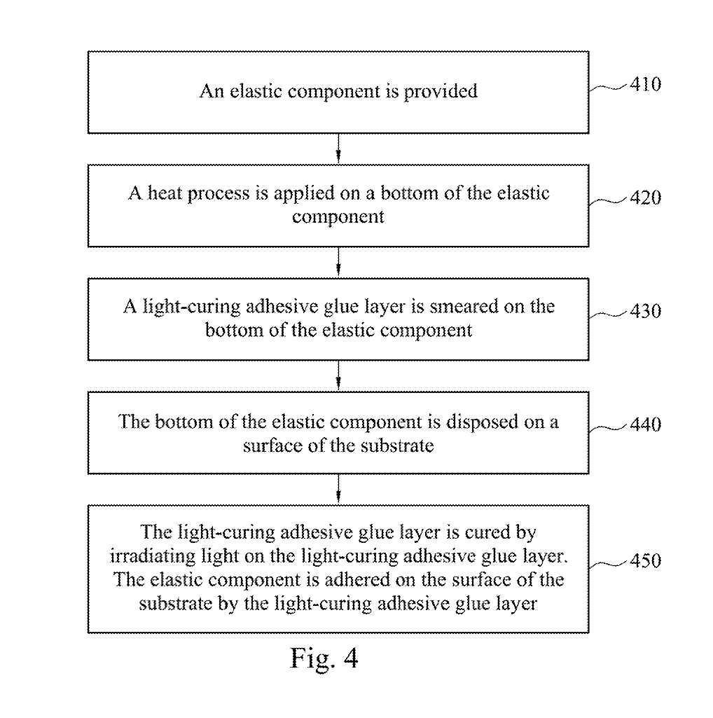

Please referring to FIG. 4, and referring to FIG. 1-3 at the same time to further clarify the present disclosure. FIG. 4 is a diagrammatic view of a method of manufacturing an elastic component substrate 100 in accordance with various embodiments. Please referring to operation 410, the elastic component 140 is provided, which the elastic component 140 is deformed when being pressed by the external force. When the external force disappears, the elastic component 140 is recovered to its original shape. In embodiments, the elastic component 140 is formed of silicone.

Continuing to operation 420, a heat process is applied on the bottom of the elastic component 140. The heat process burns grease on the bottom of the elastic component 140, and the bottom adhesive layer 144 without grease is formed on the bottom of the elastic component 140 temporarily. Temperature of the heat process s in a range from about 1000° C. to about 1200° C., and time of the heat process is in a range from about 2 seconds to about 3 seconds. In embodiments, the heat process is processed by a flame treatment machine. The flame treatment machine mixes gas and air into combustion to generate flame on a flame nozzle. The grease on the bottom of elastic component 140 is burned quickly by the instantly generated high-temperature.

Continuing to operation 430, the light-curing adhesive glue layer 160 is smeared on the bottom of the elastic component 140, and the Shore A hardness value of the light-curing adhesive glue layer 160 is lower than 90. In embodiments, the light-curing adhesive glue layer 160 is an ultraviolet light-curing adhesive glue layer. The heat process burns grease on the bottom of the elastic component 140 and forms the bottom adhesive layer 144 without grease temporarily. When smearing the light-curing adhesive glue layer 160 on the bottom of the elastic component 140, liquid light-curing adhesive glue flows into the bottom adhesive layer 144 and fill the bottom adhesive layer 144. At this time, a bond binding is formed between the light-curing adhesive glue inside the bottom adhesive layer 144 and the bottom of the elastic component 140. Adhesive strength between the light-curing adhesive glue and the elastic component 140 is enhanced substantially. In embodiments, the light-curing adhesive glue layer 160 is smeared on at least a part of the bottom of the elastic component 140.

Referring to operation 440, the bottom of the elastic component 140 is disposed on the surface of the substrate 120. The printed circuit 122 is on the surface of the substrate 120, and the elastic component 140 is disposed above the printed circuit 122 which the printed circuit 122 includes the first conductive portion 122A and the second conductive portion 122B. The elastic component 140 also includes the contact portion 146 made of conductive material. When the elastic component 140 being pressed by an external force, the contact portion 146 will contact the first conductive portion 122A and the second conductive portion 122b. Since the first conductive portion 122A and the second conductive portion 122b are electrically connected, the printed circuit 122 is turned on. In embodiments, the substrate 120 is a polymer membrane. In some embodiments, the polymer membrane is formed of poly(ethylene terephthalate) or polycarbonate. In various embodiments, the substrate 120 is a blank substrate without the printed circuit 122 thereon.

Continuing to operation 450, the light-curing adhesive glue layer 160 is cured by irradiating light on the light-curing adhesive glue layer 160. The elastic component 140 is adhered on the surface of the substrate 120 by the light-curing adhesive glue layer 160. With irradiating light on the light-curing adhesive glue layer 160, the light-curing adhesive glue layer 160 is cured. Thus, the adhesive strength between the elastic component 140 and the substrate 120 could be enhanced without baking at high temperature. Characteristic of the present disclosure is that the substrate 120 avoids deforming or bending at high temperature, and thus ensures the size accuracy of the elastic component substrate 100. Irradiating light on the light-curing adhesive glue layer 160 also shortens the time for adhering the elastic component 140 on the substrate 120, and higher adhesive strength could be achieved. In embodiments, the light is ultraviolet light, and the irradiating time is from about 10 seconds to about 30 seconds. Further, the hardness of the light-curing adhesive glue layer 160 is much softer than the traditional light-curing adhesive glue, which the light-curing adhesive glue layer 160 reduces strains and stresses when curing the elastic component 140 on the substrate 120. After curing, the elastic component 140 is conformed to specification, and the stability of the elastic component substrate 100 is enhanced significantly.

The embodiments of the present disclosure discussed above have advantages over existing structures and methods, and the advantages are summarized below. During the process of manufacturing an elastic component substrate 100, the liquid light-curing adhesive glue flows into the bottom adhesive layer 144 after applying the heat process to the bottom of the elastic component 140. Because no grease inside the bottom porous layer 144 temporarily, the bottom adhesive layer 144 is filled with the light-curing adhesive glue. The light-curing adhesive glue forms a bond binding with the bottom of the elastic component 140, and the adhesive strength between the elastic component 140 and the substrate 120 is enhanced therefore. Further, ultraviolet light make the light-curing adhesive glue layer 160 cured without baking at high temperature, and thus the substrate 120 avoids deforming or bending at high temperature to ensure the size accuracy of the elastic component substrate 100. Summarize above advantages, light-curing adhesive glue has higher curing speed and higher adhesive strength, which increases the efficiency of manufacturing the elastic component substrate 100. Besides, since the Shore A hardness value of the light-curing adhesive glue layer 160 is lower than 90, the stability of the elastic component substrate 100 is enhanced significantly.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without deportioning from the scope or spirit of the invention. In view of the foregoing, it is intended that the present invention cover modifications and variations of this invention provided they fall within the scope of the following claims.

What is claimed is:

1. A method of manufacturing an elastic component substrate, comprising:
providing a elastic component;
applying a heat process to the elastic component;
smearing a light-curing adhesive glue layer on a bottom of the elastic component, wherein a Shore A hardness value of the light-curing adhesive glue layer is lower than 90;
disposing the elastic component on a surface of the a substrate; and
irradiating light on the light-curing adhesive glue layer to cure the light-curing adhesive glue layer, wherein the elastic component is adhered on the surface of the substrate by the light-curing adhesive glue layer.

2. The method of claim 1, wherein the elastic component is formed of silicone.

3. The method of claim 1, wherein the heat process is processed by a flame treatment machine.

4. The method of claim 1, wherein the substrate is a polymer membrane.

5. The method of claim 4, wherein the polymer membrane is formed of polyethylene terephthalate) or polycarbonate.

6. The method of claim 1, wherein the substrate is a blank substrate or a substrate comprising a printed circuit.

7. The method of claim 1, wherein the light is ultraviolet light.

8. An elastic component substrate, comprising:
a substrate;
a light-curing adhesive glue layer, wherein a Shore A hardness value of the light-curing adhesive glue layer is lower than 90; and
an elastic component, a bottom of the elastic component being adhered on a surface of the substrate by the light-curing adhesive glue layer, wherein the bottom of the elastic component comprises:
a bottom adhesive layer filled with light-curing adhesive glue, wherein the bottom adhesive layer is in contact with the light-curing adhesive glue layer.

9. The elastic component substrate of claim 8, wherein the substrate is a polymer membrane.

10. The elastic component substrate of claim 9, wherein the polymer membrane is formed of polyethylene terephthalate) or polycarbonate.

11. The elastic component substrate of claim 8, wherein the substrate is a blank substrate or a substrate comprising a printed circuit.

12. The elastic component substrate of claim 8, wherein the elastic component is formed of silicone.

13. The elastic component substrate of claim 8, wherein the bottom of the elastic component further comprises an internal region, wherein the bottom adhesive layer is between the internal region and the light-curing adhesive glue layer.

14. The elastic component substrate of claim 8, wherein the light-curing adhesive glue layer is an ultraviolet light-curing adhesive glue layer.
